(19) United States
(12) Patent Application Publication
(10) Pub. No.: US 2025/0112035 A1
(43) Pub. Date: Apr. 3, 2025

(54) HYBRID SEMICONDUCTOR WAFER AND METHOD OF FORMING

(71) Applicant: Microchip Technology Incorporated, Chandler, AZ (US)

(72) Inventors: Steve Nagel, Chandler, AZ (US); Bomy Chen, Newark, CA (US); Bruce Odekirk, Portland, OR (US); Pejman Khosropour, Campbell, CA (US); Robin Liu, Fremont, CA (US); Andy Tu, Los Gatos, CA (US); Thomas Krutsick, Fleetwood, PA (US)

(73) Assignee: Microchip Technology Incorporated, Chandler, AZ (US)

(21) Appl. No.: 18/401,902

(22) Filed: Jan. 2, 2024

Related U.S. Application Data
(60) Provisional application No. 63/542,179, filed on Oct. 3, 2023.

(51) Int. Cl. H01L 21/02; H01L 29/04; H01L 29/16; H01L 29/20

(52) U.S. Cl. CPC H01L 21/02008; H10D 62/40; H10D 62/8325; H10D 62/8503

(57) ABSTRACT

A method includes performing a pressing operation on a volume of silicon carbide (SiC) powder to form a polycrystalline SiC (poly-SiC) ingot, and divide the poly-SiC ingot into a plurality of poly-SiC wafer bases. The method further includes, for a respective poly-SiC wafer base, bonding a silicon (Si) wafer structure to the respective poly-SiC wafer base to define a hybrid Si/poly-SiC stack structure, and performing a dividing process to remove a partial thickness of the Si wafer structure from the hybrid Si/poly-SiC stack structure to provide a hybrid Si/poly-SiC wafer comprising a remaining portion of the Si wafer structure bonded to the respective poly-SiC wafer base.

### RELATED APPLICATION

This application claims priority to commonly owned U.S. Provisional Patent Application No. 63/542,179 filed Oct. 3, 2023, the entire contents of which are hereby incorporated by reference for all purposes.

### TECHNICAL FIELD

The present disclosure relates to integrated circuit (IC) devices, and more particularly to hybrid semiconductor wafers for use in IC devices, and methods of forming hybrid semiconductor wafers.

### BACKGROUND

Semiconductor wafers for IC devices are commonly formed from single-crystal silicon (Si) (i.e., silicon wafers grown from a single silicon crystal), gallium arsenide (GaAs), gallium nitride (GaN), single-crystal silicon carbide (SiC), or sapphire. Different wafer materials have inherent advantages and disadvantages. For example, SiC is known as an exceptional wide bandgap semiconductor, useful for high voltage devices, e.g., high voltage power MOSFETs (metal-oxide-semiconductor field-effect transistors) and IGBTs (insulated-gate bipolar transistors). However, single crystal SiC is very difficult and expensive to manufacture, typically requiring specialized processing tools such as specialized high temperature doping/implanting equipment. In addition, single crystal SiC wafers also typically have high defect levels compared to silicon, which limits yield.

There is a need for improved semiconductor wafers for IC devices, e.g., for high voltage applications.

### SUMMARY

The present disclosure provides hybrid semiconductor wafers for IC devices, and methods of forming such hybrid wafers. As used herein, a hybrid semiconductor wafer refers to a semiconductor wafer including multiple components comprising different materials bonded together. Some examples provide a hybrid semiconductor wafer including (a) a polycrystalline SiC (poly-SiC) wafer base and (b) a device layer comprising silicon (Si) or a III-V semiconductor material (e.g., GaN) bonded to the poly-SiC wafer base.

One aspect provides a method including performing a pressing operation on a volume of silicon carbide (SiC) powder to form a polycrystalline SiC (poly-SiC) ingot, and dividing the poly-SiC ingot into a plurality of poly-SiC wafer bases. The method further includes, for a respective poly-SiC wafer base of the plurality of poly-SiC wafer bases, bonding a silicon (Si) wafer structure to the respective poly-SiC wafer base to define a hybrid Si/poly-SiC stack structure, and performing a dividing process to remove a partial thickness of the Si wafer structure from the hybrid Si/poly-SiC stack structure to provide a hybrid Si/poly-SiC wafer comprising a remaining portion of the Si wafer structure bonded to the respective poly-SiC wafer base.

In some examples, the method includes performing a further pressing operation on the hybrid Si/poly-SiC wafer to further bond the remaining portion of the Si wafer structure to the respective poly-SiC wafer base.

In some examples, the method includes using a hot press for at least one of the pressing operation on the volume of SiC powder and the further pressing operation on the hybrid Si/poly-SiC wafer.

In some examples, the method includes forming a plurality of hybrid Si/poly-SiC wafers, wherein respective hybrid Si/poly-SiC wafers comprise a respective poly-SiC wafer base of the plurality of poly-SiC wafer bases, and wherein the further pressing operation comprises loading the plurality of hybrid Si/poly-SiC wafers into a press in a stacked arrangement, and operating the press to compress the plurality of hybrid Si/poly-SiC wafers.

In some examples, loading the plurality of hybrid Si/poly-SiC wafers into the press in the stacked arrangement includes arranging a spacer element between adjacent hybrid Si/poly-SiC wafers.

In some examples, the spacer element has a lattice mismatch of at least 5% relative to both the Si wafer structure and the respective poly-SiC wafer base. In some examples, the spacer element comprises a ceramic. In some examples, the spacer element comprises boron nitride (BN), beryllium oxide (BeO), gallium oxide (GaO), or yttrium oxide (Y₂O₃).

In some examples, the method includes loading multiple SiC powder layers into a hot press to form a multi-layer powder stack, wherein different layers of SiC powder in the multi-layer powder stack have different dopant characteristics, and wherein the respective poly-SiC wafer base includes at least two SiC powder layers of the multiple SiC powder layers, wherein the at least two SiC powder layers have different dopant characteristics.

One aspect provides a hybrid semiconductor wafer including a poly-SiC wafer base and a silicon layer bonded on a first side of the poly-SiC wafer base.

In some examples, the method includes the poly-SiC wafer base includes multiple poly-SiC sub-layers having different dopant characteristics.

One aspect provides a method including forming or providing a donor wafer structure including a donor wafer base and a GaN layer formed on the donor wafer base, bonding the GaN layer of the donor wafer structure to a poly-SiC wafer base, and performing a dividing process to remove at least the donor wafer base and a partial thickness of the GaN layer to provide a hybrid GaN/poly-SiC wafer comprising a remaining portion of the GaN layer bonded to the poly-SiC wafer base.

In some examples, the method includes performing a pressing operation to further bond the remaining portion of the GaN layer to the poly-SiC wafer base.

In some examples, the method includes forming a plurality of hybrid GaN/poly-SiC wafers, wherein respective hybrid GaN/poly-SiC wafers of the plurality of hybrid GaN/poly-SiC wafers comprise a respective remaining portion of a respective GaN layer bonded to a respective poly-SiC wafer base, and wherein the pressing operation includes loading the plurality of hybrid GaN/poly-SiC wafers in a press in a stacked arrangement, and operating the press to compress the plurality hybrid GaN/poly-SiC wafers.

In some examples, loading the plurality of hybrid GaN/poly-SiC wafers in the press in the stacked arrangement includes arranging a spacer element between adjacent hybrid GaN/poly-SiC wafers.

In some examples, the spacer element has a lattice mismatch of at least 5% relative to both the GaN layer and the poly-SiC wafer base.

In some examples, the donor wafer base comprises silicon (Si), silicon carbide (SiC), sapphire, aluminum nitride (AlN), or GaN.

One aspect provides a hybrid semiconductor wafer, including a poly-SiC wafer base and a GaN layer bonded on a first side of the poly-SiC wafer base.

In some examples, the poly-SiC wafer base includes multiple poly-SiC sub-layers having different dopant characteristics.

One aspect provides a method including forming or providing a hybrid semiconductor wafer structure including a wafer base and a GaN layer formed on the wafer base, and performing at least one iteration of a dopant region formation process. A respective iteration of the dopant region formation process includes arranging a stencil on a first side of the hybrid semiconductor wafer structure, the stencil including a pattern of openings, performing a doping process through the pattern of openings in the stencil to form dopant regions in the GaN layer, and depositing additional GaN over the dopant regions in the GaN layer, the additional deposited GaN increasing a thickness of the GaN layer.

In some examples, the wafer base comprises polycrystalline SiC.

In some examples, the method includes performing multiple iterations of the dopant region formation process, wherein respective dopant regions formed by respective iterations of the dopant region formation process are separated from each other to define discrete dopant islands.

In some examples, the doping process comprises doping with a silane plasma to form silicon dopant regions in the GaN layer.

In some examples, the doping process comprises doping with a magnesium organic compound to form magnesium dopant regions in the GaN layer.

In some examples, the method includes, after performing the at least one iteration of the dopant region formation process, forming a barrier layer over the GaN layer. In some examples, forming a barrier layer over the GaN layer comprises forming an aluminum gallium nitride (AlGaN) layer.

### DESCRIPTION OF THE DRAWINGS

Example aspects of the present disclosure are described below in conjunction with the figures, in which:

FIG. 1 shows an example hybrid semiconductor wafer, i.e., a hybrid Si/poly-SiC wafer, including a silicon layer bonded on a poly-SiC wafer base;

FIGS. 2A-2F show an example process for forming multiple instances of the example hybrid Si/poly-SiC wafer shown in FIG. 1;

FIG. 3 shows an example hybrid semiconductor wafer, i.e., a hybrid GaN/poly-SiC wafer, including a GaN layer 304 bonded on a poly-SiC wafer base;

FIGS. 4A-4D show an example process for forming the example hybrid GaN/poly-SiC wafer shown in FIG. 3; and

FIGS. 5A-5G show an example process for forming an example hybrid wafer structure including a GaN layer including floating dopant regions, i.e., dopant islands.

It should be understood that the reference number for any illustrated element that appears in multiple different figures has the same meaning across the multiple figures, and the mention or discussion herein of any illustrated element in the context of any particular figure also applies to each other figure, if any, in which that same illustrated element is shown.

### DETAILED DESCRIPTION

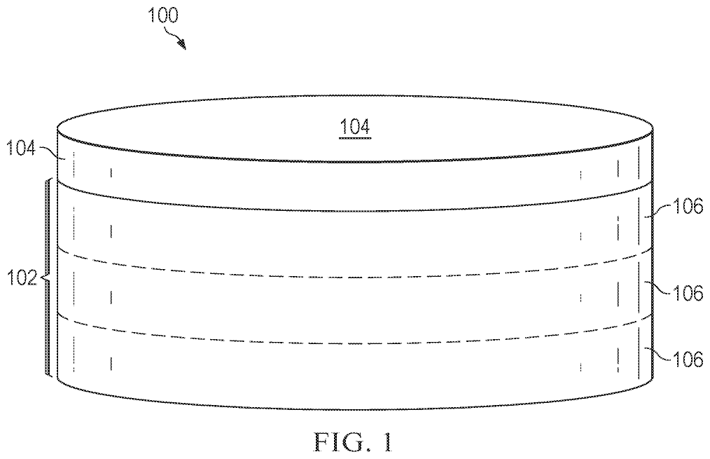

FIG. 1 shows an example hybrid semiconductor wafer 100 including a polycrystalline SiC (poly-SiC) wafer base 102 and a silicon (Si) layer 104 bonded on a first side (in the illustrated orientation, the top side) of the poly-SiC wafer base 102. The first side may also be called a first face. The example hybrid semiconductor wafer 100 is also referred to herein as a hybrid Si/poly-SiC wafer 100. In some examples, the Si layer 104 comprises single-crystal silicon, i.e., silicon grown from a single crystal.

In some examples, the poly-SiC wafer base 102 may include multiple poly-SiC sub-layers of poly-SiC material having different dopant characteristics, e.g., for use in MOSFET manufacturing. In the illustrated example, the poly-SiC wafer base 102 includes three poly-SiC sub-layers 106 having different respective dopant characteristics. Although three poly-SiC sub-layers 106 are shown in the illustrated example, the poly-SiC wafer base may include any number of poly-SiC sub-layers 106 having different dopant characteristics.

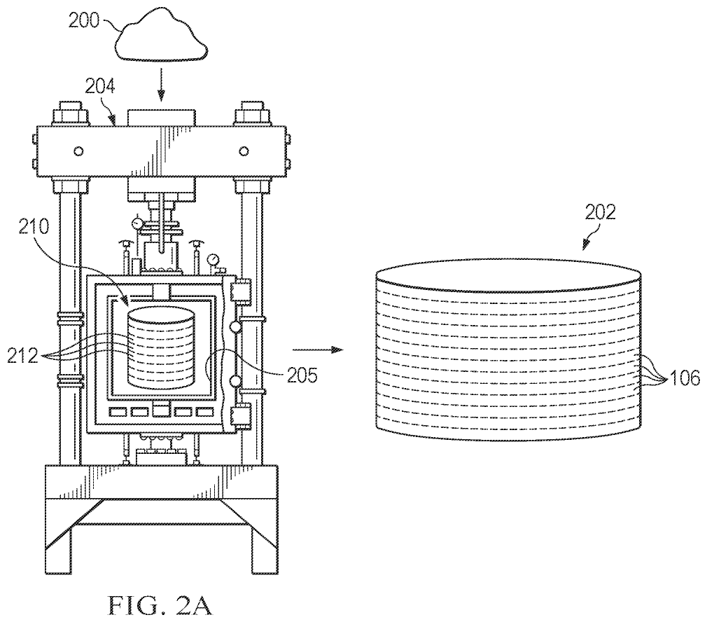

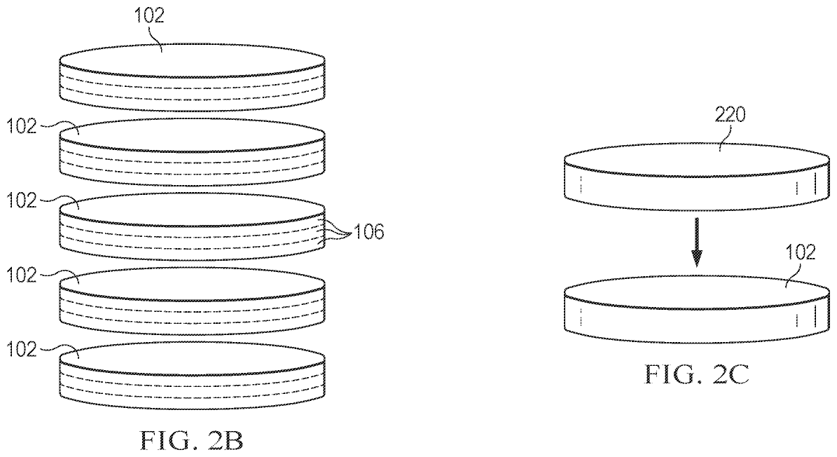

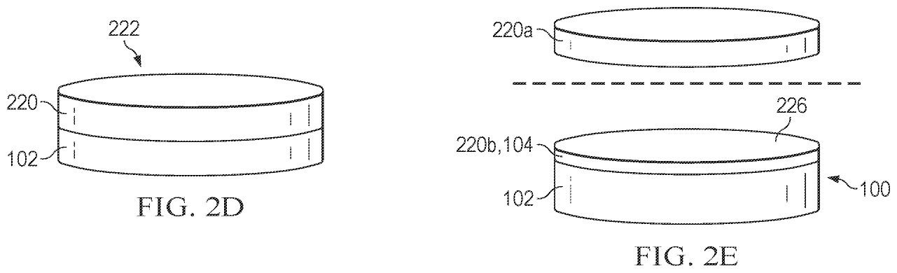

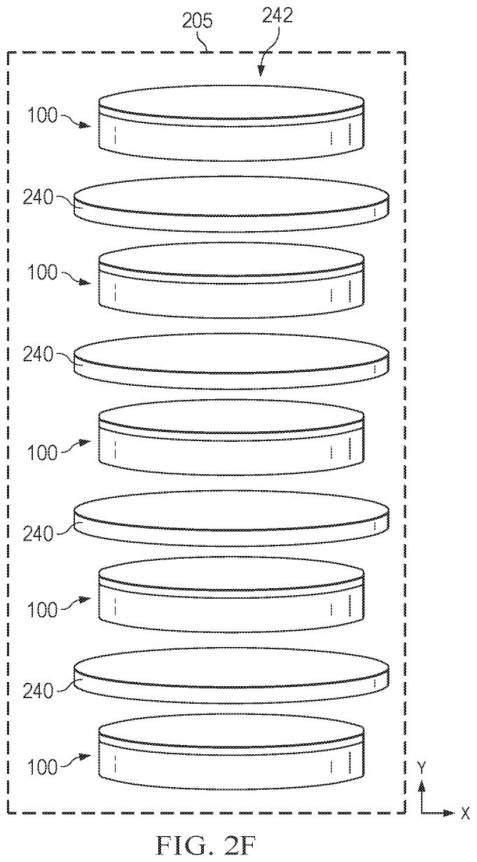

The multiple poly-SiC sub-layers 106 may be formed during the formation of the poly-SiC wafer base 102. For example, as discussed below with reference to FIGS. 2A and 2B, the poly-SiC wafer base 102 may be formed by a process including (a) loading multiple layers of SiC powder having different dopant characteristics into a press to form a multi-layer powder stack in the press, (b) operating the press to compress the multi-layer powder stack into a solid ingot having multiple poly-SiC sub-layers 106 corresponding with the multiple layers of SiC powder, and (c) slicing the ingot into multiple instances of the poly-SiC wafer base 102, wherein respective instances of the poly-SiC wafer base 102 include at least two poly-SiC sub-layers 106 corresponding with at least two of the multiple SiC powder layers.

As used herein, poly-SiC sub-layers having “different dopant characteristics” may include, for example, different dopant concentrations or other characteristics. In some examples, the poly-SiC wafer base 102 may include multiple poly-SiC sub-layers with different dopant characteristics for use in MOSFET manufacturing. For example, for certain MOSFET structures, the poly-SiC wafer base 102 may include (a) a first poly-SiC sub-layer highly doped with nitrogen (e.g., N++++), and (b) a second poly-SiC sub-layer (having a much larger thickness than the first layer of SiC powder) doped with nitrogen to a much lower level (e.g., N−).

In other examples, the poly-SiC wafer base 102 may have uniform dopant characteristics though the thickness of the poly-SiC wafer base 102, rather than having multiple poly-SiC sub-layers 106.

The hybrid Si/poly-SiC wafer 100 may provide various benefits or advantages. For example, a device formed from the hybrid Si/poly-SiC wafer 100 may realize functional benefits of SiC, for example large voltage drop, lower RDS-ON (drain-source resistance when the device is ON) and good heat dissipation, while also benefiting from the ease of processing silicon (e.g., using standard tooling), and in some instances avoiding the need for high temperature processing equipment. In addition, in some examples, the hybrid Si/poly-SiC wafer 100 may be formed in large wafer sizes, for example, 300 mm (or 12 inch) wafers.

FIGS. 2A-2F show an example process for forming multiple instances of the hybrid Si/poly-SiC wafer 100 (i.e., hybrid semiconductor wafer 100) shown in FIG. 1.

As shown in FIG. 2A, a pressing operation is performed on a volume of SiC powder 200 to form a poly-SiC ingot 202. In some examples, the SiC powder 200 may be loaded into a press 204, for example a hot press (e.g., a hot press conventionally used for forming sputter targets), which hot press may be operated to compress the SiC powder 200 to form the poly-SiC ingot 202. In some examples, the press 204 comprises a hot press, which may be operated to compress the SiC powder 200 at an operating temperature between 800-1400 C and with an operating pressure between 5 MPa and 25 MPa, for a duration between 5 minutes and 1 hour.

In some examples, the SiC powder 200 may comprise pure SiC powder or lightly doped SiC powder. In some examples, the SiC powder 200 to be loaded in the press 204 may include discrete volumes with different dopant characteristics. The discrete volumes with different dopant characteristics may be loaded into the press 204 in a defined sequence to form a multi-layer powder stack 210 in a press chamber 205 of the press 204, wherein the multi-layer powder stack 210 includes different layers 212 of SiC powder 200 having different respective dopant characteristics.

The poly-SiC ingot 202 formed from such multi-layer powder stack 210 may include multiple poly-SiC sub-layers 106 having different dopant characteristics, wherein respective poly-SiC sub-layers 106 correspond with respective SiC powder layers 212 deposited in the press 204. For example, to form a hybrid Si/poly-SiC wafer 100 used in certain MOSFET structures, the multi-layer powder stack 210 may include (a) respective first layers of SiC powder highly doped with nitrogen (e.g., N++++) alternating with (b) respective second layers of SiC powder (having a much larger thickness than the respective first layers of SiC powder) doped with nitrogen to a much lower level (e.g., N−), wherein after pressing the multi-layer powder stack 210 in the press 204, the resulting poly-SiC ingot 202 includes respective first poly-SiC sub-layers 106 (e.g., with N++++ doping) alternating with respective second poly-SiC sub-layers 106 (e.g., with N-doping). When such poly-SiC ingot 202 is divided into multiple poly-SiC wafer bases 102 as discussed below (with reference to FIG. 2B), respective poly-SiC wafer bases 102 may include a respective first poly-SiC sub-layer 106 (e.g., with N++++ doping) adjacent a respective (thicker) second poly-SiC sub-layer 106 (e.g., with N-doping).

In other examples, SiC5G powder 200 having uniform dopant characteristics is used to form a uniform powder stack in the press 104, which is compressed to form a poly-SiC ingot 202 having uniform dopant characteristics through the thickness of the ingot 202, rather than multiple poly-SiC sub-layers 106 with different dopant characteristics.

As shown in FIG. 2B, the poly-SiC ingot 202 may be divided, horizontally, into multiple poly-SiC wafer bases 102 (i.e., multiple instances of the poly-SiC wafer base 102 shown in FIG. 1). For example, the poly-SiC ingot 202 may be cut or sliced using a wire saw or other cutting tool into the multiple poly-SiC wafer bases 102. In one example, the poly-SiC ingot 202 may have a thickness of about 0.25 inch, and may be sliced into about 12 poly-SiC wafer bases 102 having a respective thickness in the range of 500-750 μm. In examples in which the poly-SiC ingot 202 includes multiple poly-SiC sub-layers 106, respective instances of the poly-SiC wafer base 102 may include a stacked arrangement of the same two or more poly-SiC sub-layers 106 having different dopant characteristics.

In some examples, the respective poly-SiC wafer bases 102 may optionally be lapped, grinded, polished, and/or otherwise treated before further processing.

As shown in FIGS. 2C and 2D, a silicon (Si) wafer structure 220 may be bonded to a respective poly-SiC wafer base 102, e.g., by a direct contact bond, to define a hybrid Si/poly-SiC stack structure 222. In some examples, the Si wafer structure 220 comprises single-crystal silicon, i.e., silicon grown from a single crystal.

As shown in FIG. 2E, a dividing process is performed to remove a partial portion 220a of the Si wafer structure 220 (the removed partial portion 220a comprising a partial thickness of the Si wafer structure 220) from the hybrid Si/poly-SiC stack structure 222 to provide the hybrid Si/poly-SiC wafer 100 shown in FIG. 1, comprising a remaining portion 220b of the Si wafer structure 220 (the remaining portion 220b comprising a remaining thickness of the Si wafer structure 220) bonded to the respective poly-SiC wafer base 102. The remaining portion 220b of the Si wafer structure 220 corresponds with the Si layer 104 shown in FIG. 1, and thus the remaining portion 220b of the Si wafer structure 220 is referred to below as Si layer 104 for simplicity.

The dividing process, indicated by the dashed line in FIG. 2E, may comprise any suitable sawing or cutting process. In some examples, an exposed cut surface 226 of the Si layer 104 may be polished and/or otherwise treated. The removed partial portion 220a of the Si wafer structure 220 may be reused, e.g., as a substrate for respective integrated circuit device(s).

In some examples, an optional pressing procedure as shown FIG. 2F may be performed to further bond the Si layer 104 (i.e., the remaining portion 220b of the Si wafer structure 220) to the poly-SiC wafer base 102, wherein “further bonding” refers to improving or strengthening the bond between the Si layer 104 and the poly-SiC wafer base 102. As shown in FIG. 2F, multiple instances of the hybrid Si/poly-SiC wafer 100 (e.g., respectively formed according to the operations shown in FIGS. 2C-2E) may be loaded in the press chamber 205 of the press 204 (or in a different press in another example) in a stacked arrangement, with a respective spacer element 240 arranged between adjacent hybrid Si/poly-SiC wafers 100, to define a wafer/spacer stack 242 in the press chamber 205.

The press 204 may be operated to compress the wafer/spacer stack 242 to thereby further bond the respective Si layer 104 to the respective poly-SiC wafer base 102 of respective hybrid Si/poly-SiC wafers 100. In some examples, the press 204 may comprise a hot press used for both the pressing operation shown in FIG. 2A and the optional pressing operation shown in FIG. 2F. In an example in which the same hot press is used for both operations, the hot press may be (a) operated for the pressing operation shown in FIG. 2A according to the example operational parameters discussed above (i.e., an operating temperature between 800-1400 C and an operating pressure between 5 MPa and 25 MPa, for a duration between 5 minutes and 1 hour), and (b) operated for the pressing operation shown in FIG. 2F according to more aggressive operational parameters, for example, with an operating temperature between 1200-1800 C and an operating pressure between 30 MPa and 90 MPa, for a duration between 10 hours and 100 hours.

The spacer elements 240 may facilitate the separation of adjacent hybrid Si/poly-SiC wafers 100 after the pressing operation, e.g., by preventing the adjacent hybrid Si/poly-SiC wafers 100 from bonding to each other. In some examples, spacer elements 240 may have a lattice mismatch of at least 5%, or at least 15%, or at least 25%, relative to both Si layer 104 and poly-SiC wafer base 102. In some examples, spacer elements 240 may have a melting point above 2500 C, and a thickness (in the y-direction shown in FIG. 2F) greater than 1000 μm. In some examples, spacer elements 240 may comprise an amorphous ceramic or other ceramic material, for example, boron nitride (BN), beryllium oxide (BeO), gallium oxide (GaO), or yttrium oxide (Y₂O₃), without limitation. As shown in FIG. 2F, spacer elements 240 may have a lateral width (in the x-direction shown in FIG. 2F) extending beyond the lateral width of respective hybrid Si/poly-SiC wafers 100, e.g., as indicated, to facilitate separation (e.g., peeling) of respective spacer elements 240 from adjacent hybrid Si/poly-SiC wafers 100.

In other examples, the pressing operation shown in FIG. 2F may be performed prior to (rather than after) the dividing operation shown in FIG. 2E. In other words, multiple instances of the hybrid Si/poly-SiC stack structure 222 shown in FIG. 2D may be loaded in the press chamber 205 of the press 204 (or in a different press in another example) in a stacked arrangement, with respective spacer elements 240 arranged between adjacent hybrid Si/poly-SiC stack structures 222, to define the wafer/spacer stack 242 in the press chamber 205. The press 204 may be operated to compress the wafer/spacer stack 242 to thereby further bond the respective Si wafer structure 220 to the respective poly-SiC wafer base 102 of respective hybrid Si/poly-SiC stack structures 222. The spacer elements 240 may then be removed, and the dividing operation shown in FIG. 2E (discussed above) may be performed on respective hybrid Si/poly-SiC stack structures 222.

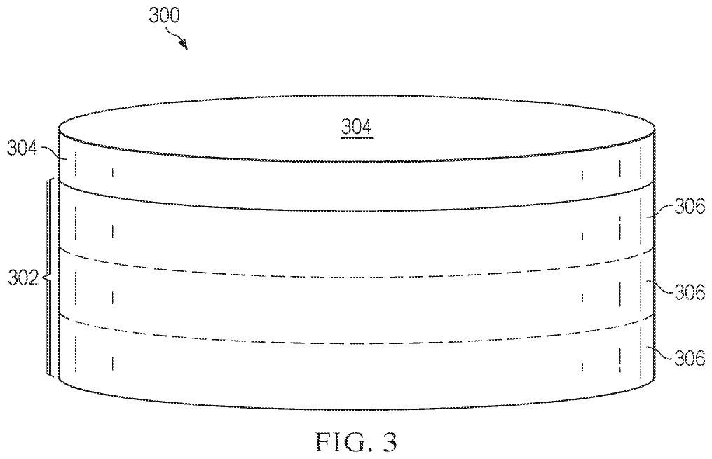

FIG. 3 shows an example hybrid semiconductor wafer 300 including a poly-SiC wafer base 302 and a gallium nitride (GaN) layer 304 bonded on a first side (in the illustrated orientation, the top side) of the poly-SiC wafer base 302. The first side may also be called a first face. The example hybrid semiconductor wafer 300 is also referred to herein as a hybrid GaN/poly-SiC wafer 300.

In some examples, the poly-SiC wafer base 302 may correspond with the poly-SiC wafer base 102 of the hybrid semiconductor wafer 100 discussed above. Accordingly, the poly-SiC wafer base 302 may be formed according to the process shown in FIGS. 2A and 2B discussed above, and may optionally include multiple poly-SiC sub-layers 306 having different respective dopant characteristics, e.g., as discussed above regarding poly-SiC sub-layers 106 of the poly-SiC wafer base 102.

In other examples, the GaN layer 304 may alternatively comprise another III-V semiconductor material, for example, indium phosphate (InP), indium arsenide (InAs), gallium arsenide (GaAs), or indium antimonide (InSb), without limitation. In such examples, GaN layer 404 discussed below may be substituted by a layer of the other III-V semiconductor material, within the scope of the present disclosure.

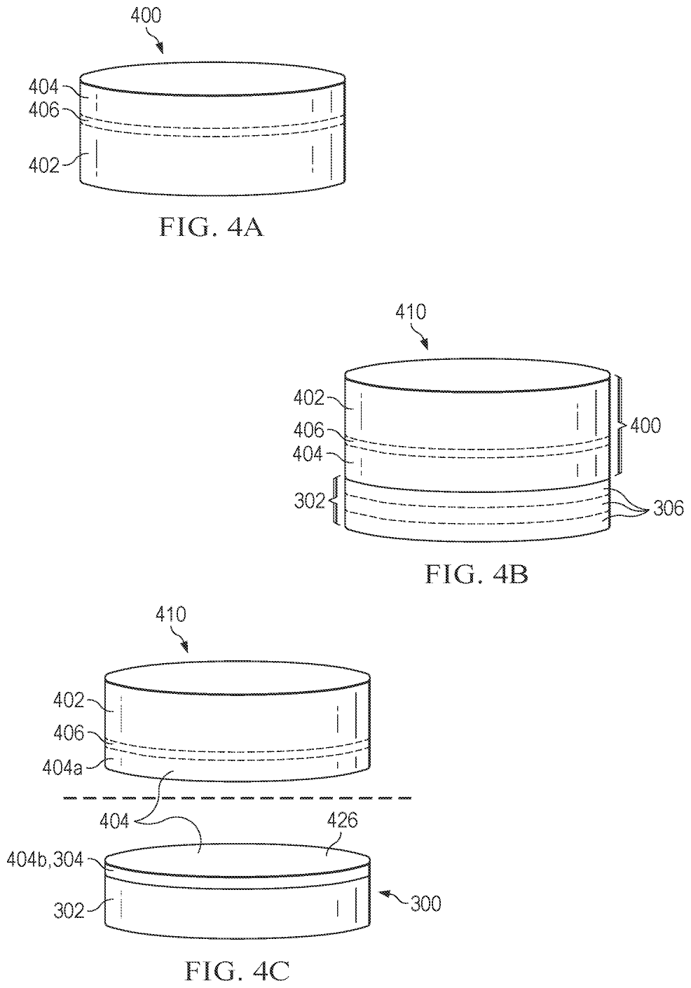

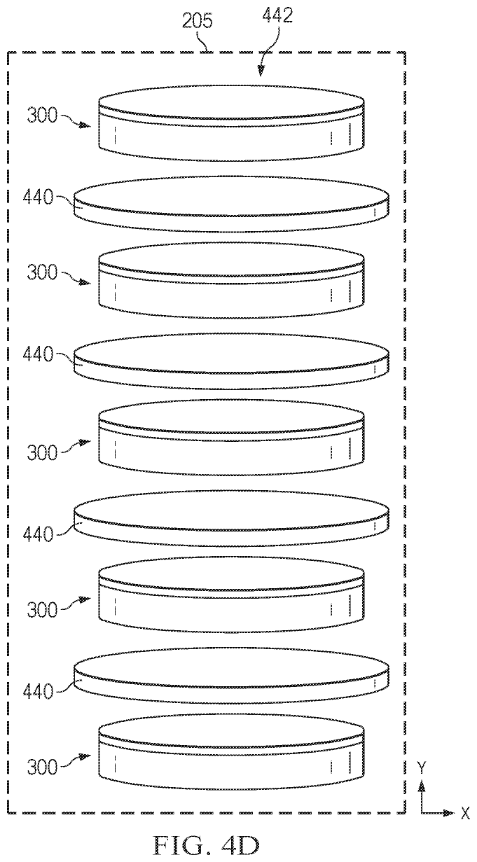

FIGS. 4A-4D show an example process for forming the example hybrid GaN/poly-SiC wafer 300 (i.e., hybrid semiconductor wafer 300) shown in FIG. 3.

As shown in FIG. 4A, a donor wafer structure 400 is formed or provided, wherein the donor wafer structure 400 includes a donor wafer base 402 and a GaN layer 404 formed (directly or indirectly) on the donor wafer base 402. The donor wafer base 402 may comprise silicon (e.g., single crystal silicon), SiC (e.g., single crystal SiC), sapphire, aluminum nitride (AlN), GaN, or other suitable material or materials.

In some examples, the GaN layer 404 may be formed directly on the donor wafer base 404. For example, the GaN layer 404 may be grown on the donor wafer base 404 or deposited by a metal-organic chemical vapor deposition (MOCVD) process. In other examples, the GaN layer 404 may be formed indirectly on the donor wafer base 404. For example, in examples in which donor wafer base 404 is formed from single crystal silicon, an optional buffer layer 406 (e.g., comprising aluminum nitride (AlN) or other suitable material) is formed on the donor wafer base 404, and the GaN layer 404 may be grown or deposited (e.g., by MOCVD) on the buffer layer 406. In such an example, the buffer layer 406 may facilitate improved bonding between the GaN layer 404 and single crystal Si donor wafer base 404.

As shown in FIG. 4B, the GaN layer 404 of the donor wafer structure 400 may be bonded to a respective poly-SiC wafer base 302, e.g., by a direct contact bond, to define a donor wafer/poly-SiC stack structure 410. As discussed above, in some examples the poly-SiC wafer base 302 may be formed according to the process shown in FIGS. 2A and 2B discussed above, and may optionally include multiple poly-SiC sub-layers 306 having different dopant characteristics.

As shown in FIG. 4C, a dividing process is performed to remove the donor wafer base 402, the optional buffer layer 406 (if present), and a partial portion 404a of the GaN layer 404 (the removed partial portion 404a comprising a partial thickness of the GaN layer 404) from the donor wafer/poly-SiC stack structure 410, leaving the hybrid GaN/poly-SiC wafer 300 shown in FIG. 3, comprising a remaining portion 404b of the GaN layer 404 (the remaining portion 404b comprising a remaining thickness of the GaN layer 404) bonded to the poly-SiC wafer base 302 The remaining portion 404b of the GaN layer 404 corresponds with the GaN layer 304 shown in FIG. 3, and thus the remaining portion 404b of the GaN layer 404 is referred to below as GaN layer 304 for simplicity.

The dividing process, indicated by the dashed line in FIG. 4C, may comprise any suitable sawing or cutting process. In some examples, an exposed cut surface 426 of the GaN layer 304 may be polished and/or otherwise treated.

In some examples, an optional pressing procedure as shown FIG. 4D may be performed to further bond the GaN layer 304 (i.e., the remaining portion 404b of the GaN layer 404) to the poly-SiC wafer base 302, wherein “further bonding” refers to improving or strengthening the bond between the GaN layer 304 and poly-SiC wafer base 302. As shown in FIG. 4D, multiple instances of the hybrid GaN/poly-SiC wafer 300 (e.g., respectively formed according to the operations shown in FIGS. 4A-4C) may be loaded in the press chamber 205 of press 204 shown in FIG. 2A (or other press) in a stacked arrangement, with a respective spacer element 440 arranged between adjacent hybrid GaN/poly-SiC wafers 300, to define a wafer/spacer stack 442 in the press chamber 205. The press 204 may be operated to compress the wafer/spacer stack 442 to thereby further bond the respective GaN layer 304 to the respective poly-SiC wafer base 302 of respective hybrid GaN/poly-SiC wafers 300.

The spacer elements 440 may facilitate the separation of adjacent hybrid GaN/poly-SiC wafers 300 after the pressing operation, e.g., by preventing the adjacent hybrid GaN/poly-SiC wafers 300 from bonding to each other. In some examples, spacer elements 440 may have a lattice mismatch of at least 5%, or at least 15%, or at least 25%, relative to both GaN layer 304 and poly-SiC wafer base 302. In some examples, spacer elements 440 may have a melting point above 2500 C, and a thickness (in the y-direction shown in FIG. 4D) greater than 1000 μm. In some examples, spacer elements 440 may comprise an amorphous ceramic or other ceramic material, for example, boron nitride (BN), beryllium oxide (BeO), gallium oxide (GaO), or yttrium oxide (Y₂O₃), without limitation. As shown in FIG. 4D, spacer elements 440 may have a lateral width (in the x-direction shown in FIG. 4D) extending beyond the lateral width of respective hybrid GaN/poly-SiC wafers 300, e.g., as indicated, to facilitate separation (e.g., peeling) of respective spacer elements 440 from adjacent hybrid GaN/poly-SiC wafers 300.

In other examples, the pressing operation shown in FIG. 4D may be performed prior to (rather than after) the dividing operation shown in FIG. 4E. In other words, multiple instances of the donor wafer/poly-SiC stack structure 410 shown in FIG. 4B may be loaded in the press chamber 205 in a stacked arrangement, with respective spacer elements 440 arranged between adjacent donor wafer/poly-SiC stack structures 410. The press 204 may be operated to further bond the respective GaN layer 404 to the respective poly-SiC wafer base 302 of respective donor wafer/poly-SiC stack structures 410. The spacer elements 440 may then be removed, and the dividing operation shown in FIG. 4C (discussed above) may be performed on respective donor wafer/poly-SiC stack structures 410.

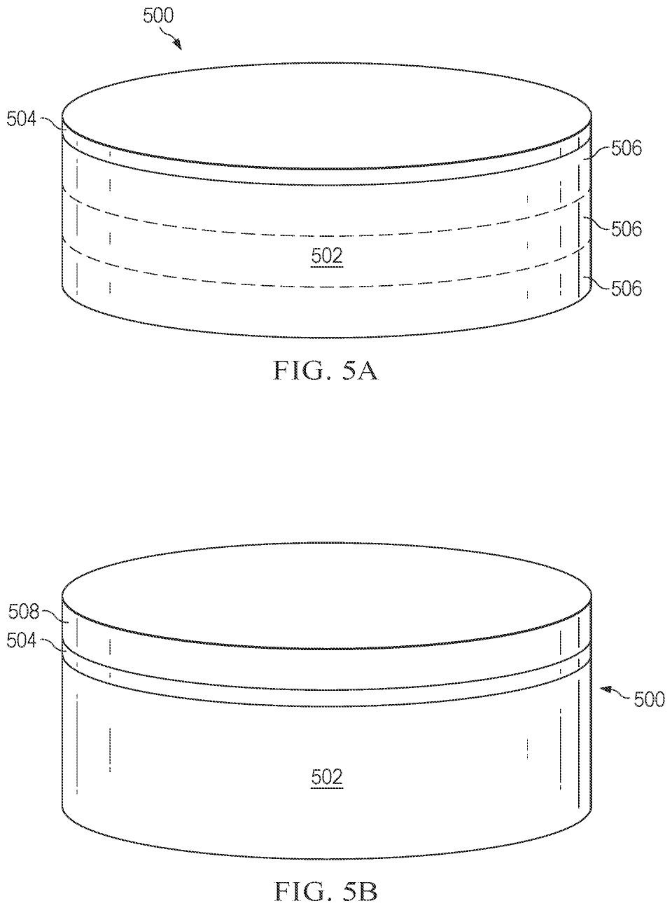

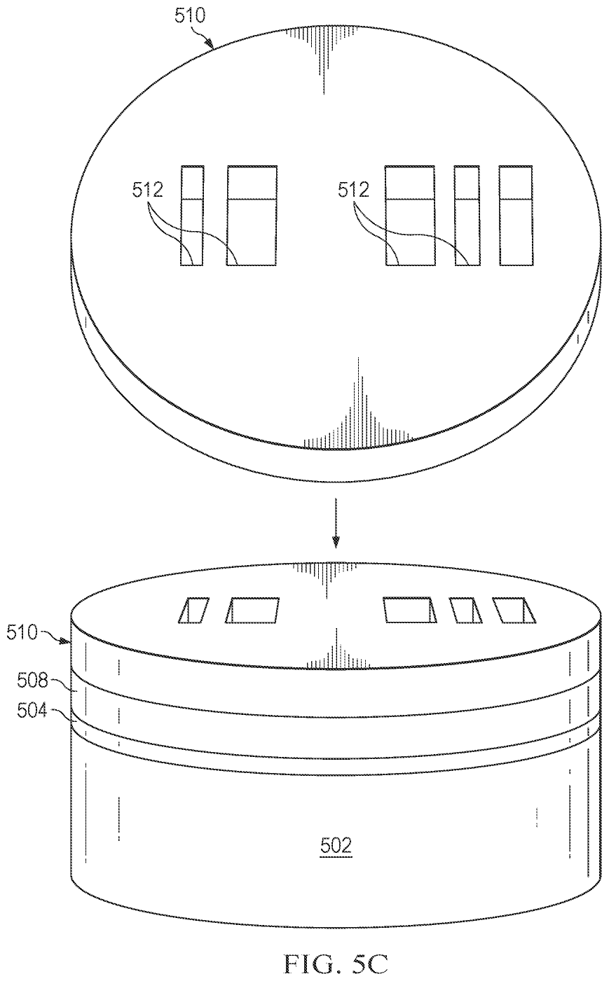

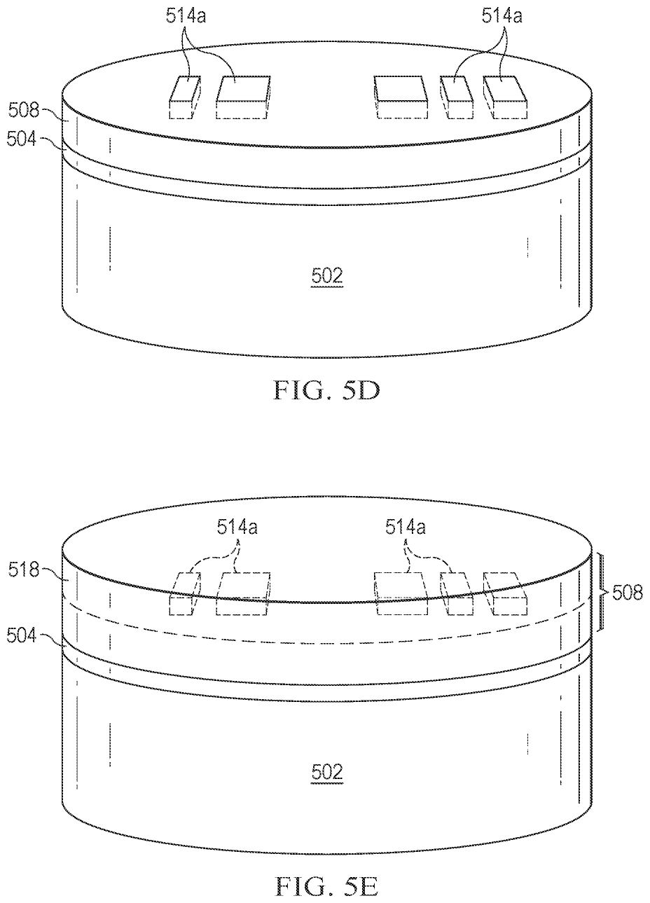

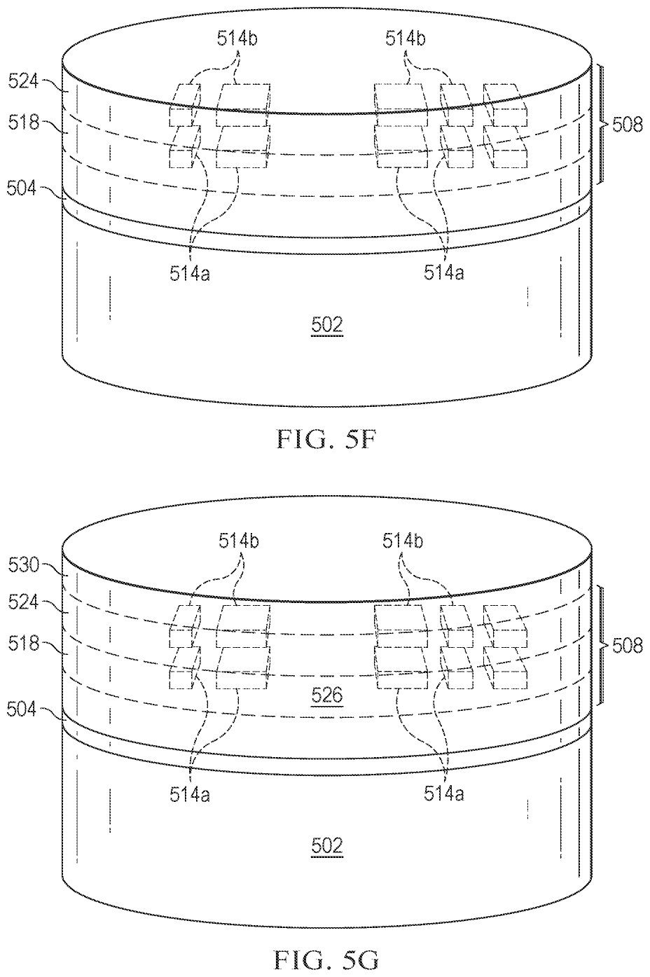

FIGS. 5A-5G show an example process for forming an example wafer structure (e.g., a MOSFET structure) including a GaN layer including floating dopant regions, or dopant “islands” in the GaN layer.

As shown in FIG. 5A, a hybrid semiconductor wafer structure 500, including a wafer base 502 and a GaN layer 504 formed on the wafer base 502, is formed or provided. In some examples, the wafer base 502 may comprise poly-SiC. In such examples, the hybrid semiconductor wafer structure 500 may correspond with the example hybrid semiconductor wafer 300, i.e., hybrid GaN/poly-SiC wafer 300. Accordingly, the wafer base 502 may comprise a poly-SiC wafer base formed according to the process shown in FIGS. 2A and 2B, and may optionally include multiple poly-SiC sub-layers 506 having different dopant characteristics, e.g., as discussed above regarding poly-SiC sub-layers 106 of the poly-SiC wafer base 102. In other examples, the wafer base 502 may comprise indium phosphate (InP), indium arsenide (InAs), gallium arsenide (GaAs), or indium antimonide (InSb), without limitation.

As shown in FIG. 5B, an additional GaN layer 508 may be formed on the hybrid semiconductor wafer structure 500. In some examples, a layer of n-type doped GaN may be deposited (e.g., by MOCVD) on the GaN layer 504 to define an n-type GaN layer 508. In other examples, a layer of p-type doped GaN may be deposited (e.g., by MOCVD) on the GaN layer 504 to define a p-type GaN layer 508.

The method may continue by performing at least one iteration of a dopant region formation process to increase the thickness of the GaN layer 508 and form floating dopant regions (i.e., dopant islands) in the GaN layer 508, to thereby define a transistor drift region 526.

A first iteration of the dopant region formation process is shown in FIGS. 5C through 5E. As shown in FIG. 5C, a stencil 510 including a pattern of openings 512 is arranged on the GaN layer 508, wherein selected areas of the GaN layer 508 are exposed though the openings 512. As shown in FIG. 5D, a doping process is performed through the pattern of openings 512 in the stencil 510 to form a plurality of first dopant regions 514a in the GaN layer 508. In some examples, the doping process may include (a) doping with silane, i.e. SiH₄, plasma (e.g., for an n-type GaN layer 508) to form silicon dopant regions 514a in the GaN layer 508, (b) doping with a magnesium organic compound (for a p-type GaN layer 508) to form magnesium dopant regions 514a in the GaN layer 508, or (c) doping with another suitable dopant.

As shown in FIG. 5E, additional GaN 518 may be deposited (e.g., by MOCVD) on the GaN layer 508 and covering the first dopant regions 514a, the additional deposited GaN 518 increasing the thickness of the GaN layer 508. The additional GaN 518 may have the same doping (n-type or p-type) as the previously deposited GaN of the GaN layer 508.

The dopant region formation process shown in FIGS. 5C through 5E may be repeated to further increase the thickness of GaN layer 508 and form additional floating dopant regions (i.e., dopant islands) in the GaN layer 508. For example, FIG. 5F shows the result after a second iteration of the dopant region formation process shown in FIGS. 5C through 5E, wherein a plurality of second dopant regions 514b are formed in the GaN layer 508, and additional GaN 524 is deposited (e.g., by MOCVD) over the second dopant regions 514b, the additional deposited GaN 524 increasing the thickness of the GaN layer 508. As shown in FIG. 5F, respective first and second dopant regions 514a and 514b are spaced apart from other first and second dopant regions 514a and 514b, such that respective first and second dopant regions 514a and 514b define floating dopant regions or dopant islands in the GaN layer 508. Respective dopant regions 514a are spaced apart vertically from respective dopant regions 514b, while respective dopant regions 514a and 514b are spaced apart horizontally from other dopant regions 514a and 514b. The dopant region formation process shown in FIGS. 5C through 5E may be repeated one or more additional times to further increase the GaN layer 508 to a desired thickness and form additional floating dopant regions (dopant islands). In some examples, the same stencil 510 may be used to form each group of dopant regions (e.g., first dopant regions 514a, second dopant regions 514b, and so on) to thereby create vertical pathways through the GaN layer 508 that alternate between doped GaN and undoped (or differently doped) GaN, e.g., for use in a vertical MOSFET device.

As shown in FIG. 5G, in some examples, after repeating the dopant region formation process to increase the GaN layer 508 to the desired thickness, a barrier layer 530 may be formed over the GaN layer 508. The barrier layer 530 may comprise an aluminum gallium nitride (AlGaN) layer, for example. The resulting structure may define a GaN MOSFET structure, wherein the GaN layer 508 including dopant islands (e.g., dopant islands 514a and 514b) defines a MOSFET drift region, which may exhibit breakdown voltages of greater than 2400V, for example.

Although example embodiments have been described above, other variations and embodiments may be made from this disclosure without departing from the spirit and scope of these embodiments.

1. A method, comprising:
performing a pressing operation on a volume of silicon carbide (SiC) powder to form a polycrystalline SiC (poly-SiC) ingot;
dividing the poly-SiC ingot into a plurality of poly-SiC wafer bases;
for a respective poly-SiC wafer base of the plurality of poly-SiC wafer bases:
bonding a silicon (Si) wafer structure to the respective poly-SiC wafer base to define a hybrid Si/poly-SiC stack structure; and
performing a dividing process to remove a partial thickness of the Si wafer structure from the hybrid Si/poly-SiC stack structure to provide a hybrid Si/poly-SiC wafer comprising a remaining portion of the Si wafer structure bonded to the respective poly-SiC wafer base.

2. The method of claim 1, comprising performing a further pressing operation on the hybrid Si/poly-SiC wafer to further bond the remaining portion of the Si wafer structure to the respective poly-SiC wafer base.

3. The method of claim 2, comprising using a hot press for at least one of the pressing operation on the volume of SiC powder and the further pressing operation on the hybrid Si/poly-SiC wafer.

4. The method of claim 2, comprising:
forming a plurality of hybrid Si/poly-SiC wafers, wherein respective hybrid Si/poly-SiC wafers of the plurality of hybrid Si/poly-SiC wafers comprise a respective poly-SiC wafer base of the plurality of poly-SiC wafer bases; and
wherein the further pressing operation comprises:
loading the plurality of hybrid Si/poly-SiC wafers into a press in a stacked arrangement; and
operating the press to compress the plurality of hybrid Si/poly-SiC wafers.

5. The method of claim 4, wherein loading the plurality of hybrid Si/poly-SiC wafers into the press in the stacked arrangement includes arranging a spacer element between adjacent hybrid Si/poly-SiC wafers.

6. The method of claim 5, wherein the spacer element has a lattice mismatch of at least 5% relative to both the Si wafer structure and the respective poly-SiC wafer base.

7. The method of claim 5, wherein the spacer element comprises a ceramic.

8. The method of claim 5, wherein the spacer element comprises boron nitride (BN), beryllium oxide (BeO), gallium oxide (GaO), or yttrium oxide (Y₂O₃).

9. The method of claim 1, comprising:
loading multiple SiC powder layers into a hot press to form a multi-layer powder stack, wherein different layers of SiC powder in the multi-layer powder stack have different dopant characteristics; and
wherein the respective poly-SiC wafer base includes at least two SiC powder layers of the multiple SiC powder layers, wherein the at least two SiC powder layers have different dopant characteristics.

10. A hybrid semiconductor wafer, comprising:
a polycrystalline SiC (poly-SiC) wafer base; and
a silicon (Si) layer bonded on a first side of the poly-SiC wafer base.

11. The hybrid semiconductor wafer of claim 10, wherein the poly-SiC wafer base includes multiple poly-SiC sub-layers having different dopant characteristics.

12. A method, comprising:
forming or providing a donor wafer structure including a donor wafer base and a gallium nitride (GaN) layer formed on the donor wafer base;
bonding the GaN layer of the donor wafer structure to a polycrystalline SiC (poly-SiC) wafer base; and
performing a dividing process to remove at least the donor wafer base and a partial thickness of the GaN layer to provide a hybrid GaN/poly-SiC wafer comprising a remaining portion of the GaN layer bonded to the poly-SiC wafer base.

13. The method of claim 12, comprising performing a pressing operation to further bond the remaining portion of the GaN layer to the poly-SiC wafer base.

14. The method of claim 13, comprising:
forming a plurality of hybrid GaN/poly-SiC wafers, wherein respective hybrid GaN/poly-SiC wafers of the plurality of hybrid GaN/poly-SiC wafers comprise a respective remaining portion of a respective GaN layer bonded to a respective poly-SiC wafer base; and
wherein the pressing operation comprises:
loading the plurality of hybrid GaN/poly-SiC wafers in a press in a stacked arrangement; and
operating the press to compress the plurality hybrid GaN/poly-SiC wafers.

15. The method of claim 13, wherein loading the plurality of hybrid GaN/poly-SiC wafers in the press in the stacked arrangement includes arranging a spacer element between adjacent hybrid GaN/poly-SiC wafers.

16. The method of claim 15, wherein the spacer element has a lattice mismatch of at least 5% relative to both the GaN layer and the poly-SiC wafer base.

17. The method of claim 12, wherein the donor wafer base comprises silicon (Si), silicon carbide (SiC), sapphire, aluminum nitride (AlN), or GaN.

18. A hybrid semiconductor wafer, comprising:
a polycrystalline SiC (poly-SiC) wafer base; and
a gallium nitride (GaN) layer bonded on a first side of the poly-SiC wafer base.

19. The hybrid semiconductor wafer of claim 18, wherein the poly-SiC wafer base includes multiple poly-SiC sub-layers having different dopant characteristics.

20. A method, comprising:
forming or providing a semiconductor wafer structure including a wafer base and a gallium nitride (GaN) layer formed on the wafer base;
performing at least one iteration of a dopant region formation process, wherein a respective iteration of the dopant region formation process includes:
arranging a stencil on a first side of the semiconductor wafer structure, the stencil including a pattern of openings;
performing a doping process through the pattern of openings in the stencil to form dopant regions in the GaN layer; and
depositing additional GaN over the dopant regions in the GaN layer, the additional deposited GaN increasing a thickness of the GaN layer.
